(19) United States
(12) Patent Application Publication
(10) Pub. No.: US 2021/0083050 A1
(43) Pub. Date: Mar. 18, 2021

(54) SILICON NANOTUBE, NEGATIVE-CAPACITANCE TRANSISTOR WITH FERROELECTRIC LAYER AND METHOD OF MAKING

(71) Applicant: KING ABDULLAH UNIVERSITY OF SCIENCE AND TECHNOLOGY, Thuwal (SA)

(72) Inventors: Muhammad Mustafa HUSSAIN, Hercules, CA (US); Nazek Mohamad EL-ATAB, Thuwal (SA)

(21) Appl. No.: 16/772,016

(22) PCT Filed: Nov. 15, 2018
(86) PCT No.: PCT/IB2018/059007

§ 371 Date: Jun. 11, 2020

Related U.S. Application Data
(60) Provisional application No. 62/674,693, filed on May 22, 2018.
(60) Provisional application No. 62/610,375, filed on Dec. 26, 2017.

(51) Int. Cl. H01L 29/06; H01L 29/66; H01L 29/775; H01L 29/78

(52) U.S. Cl. CPC H01L 29/0676; H01L 29/66439; H01L 29/78391; H01L 29/7827; H01L 29/7831; H01L 29/775

(57) ABSTRACT

There is a an electronic device that includes a substrate; a body including plural layers, the body being formed on top of the substrate; a nanotube trench formed vertically in the body and extending to the substrate; and a nanotube structure formed in the nanotube trench. The nanotube structure is mechanically separated from the body by a gate dielectric layer and a ferroelectric layer.

### CROSS-REFERENCE TO RELATED APPLICATIONS

This application claims priority to U.S. Provisional Patent Application No. 62/610,375, filed on Dec. 26, 2017, entitled “SI NANOTUBE NEGATIVE-CAPACITANCE FIELD EFFECT TRANSISTOR FOR LOW-POWER NANOSCALE DEVICES,” and U.S. Provisional Patent Application No. 62/674,693, filed on May 22, 2018, entitled “SILICON NANOTUBE, NEGATIVE-CAPACITANCE TRANSISTOR WITH FERROELECTRIC LAYER AND METHOD OF MAKING,” the disclosures of which are incorporated herein by reference in their entirety.

### BACKGROUND

### Technical Field

Embodiments of the subject matter disclosed herein generally relate to a silicon nanotube negative-capacitance transistor, and more specifically, to a silicon nanotube negative-capacitance field effect transistor with ferroelectric layers that uses low-power.

### Discussion of the Background

Currently, all the online activities in the United States are driven by 12 million servers which are distributed in 3 million data centers, and their total energy consumption per year is 76 TW-hr, which constitutes almost 2% of the total US electricity consumption in 2011. With the exponential growth of information infrastructure, the power consumption will soon reach unmanageable levels. In addition, with the explosive growth of Internet of Things (IoT) devices, where trillions of small stand-alone sensors and devices will be interconnected and integrated, the number of devices connected to the internet is expected to grow to 20 billion by 2020. Therefore, power dissipation and management concerns in the information infrastructure will intimidate the pace of the revolutions in the approaching years.

In the past four decades, the downscaling of CMOS technology following Moore's law has been the main driver for the information revolution. However, the downscaling of the devices was not able to achieve the energy efficiency needed, and the drain voltage V_{dd} applied to the drain of a transistor was not able to scale below 1 V for almost 15 years. In addition, the clock frequency remained at about 3 GHz after 2005 due to the unmanageable power density beyond 100 W/cm². In fact, due to power management challenges, 50% of the sub-10 nm technology node microprocessors are expected to be turned off at a single time, and the age of “Dark Silicon” has already started.

Thus, modern electronic devices and evolving IoT technologies require extremely low-power, large-scale-integration and low-cost systems. IoT devices are expected to operate using energy harvesters instead of a battery exchange or power supply. Thus, ultralow power consumption (e.g., sub 1 μW) is needed for data sensing/processing/communication in this field. The great majority of the IoT devices include one or more transistors. Therefore, if the power consumption at the transistor level can be decreased, the entire IoT device's power would decrease.

At the transistor level, the most effective way to decrease the power consumption is to reduce the drain voltage V_{dd}. However, this approach results in a lower Iₒₙ and higher circuit delay while the leakage current keeps flowing. For mobile computing and IoT applications, it is preferable that the devices complete the tasks during a short active period and then they can stand-by in a sleep mode, which makes the switching energy an essential metric in low-power devices.

Therefore, to reduce the power consumption and realize energy-efficient switching, the ratio of the on and off currents Iₒₙ/I_{off} has to be maximized. Thus, there is a need to design a small transistor that is capable of using low-power and is not being affected by the above discussed shortcomings.

### SUMMARY

According to an embodiment, there is an electronic device that includes a substrate, a body including plural layers, the body being formed on top of the substrate, a nanotube trench formed vertically in the body and extending to the substrate, and a nanotube structure formed in the nanotube trench. The nanotube structure is mechanically separated from the body by a gate dielectric layer and a ferroelectric layer.

According to another embodiment, there is a nanotube, negative capacitance, field effect transistor with ferromagnetic layers. The transistor includes a substrate, a body including plural layers, the body being formed on top of the substrate, a nanotube trench formed vertically into the body and extending to the substrate, and a source region, a channel region and a drain region formed vertically on top of each other within the nanotube trench. The source region, the channel region and the drain region are encircled along an internal circumference by a first gate dielectric layer and by a first ferroelectric layer, in this order, and also are encircled, along an external circumference, by a second gate dielectric layer and by a second ferroelectric layer.

According to still another embodiment, there is a method for forming an electronic device. The method includes providing a substrate, forming a body, including plural layers, on the substrate, etching a nanotube trench vertically into the body, forming a ferroelectric layer on the sides of the nanotube trench, depositing a gate dielectric layer on the ferroelectric layer, and growing a nanotube structure in the nanotube trench. The nanotube structure is separated from the body by the gate dielectric layer and the ferroelectric layer and the nanotube structure includes a source region, a channel region and a drain region.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 illustrates a profile of the carrier in a transistor;

FIG. 2 illustrates a profile of the carrier in a gate-all-around nanowire field effect transistor;

FIG. 3 compares a gate-all-around nanowire field effect transistor and a nanotube field effect transistor;

FIG. 4 illustrates an overall view of a nanotube, negative capacitance field effect transistor with ferroelectric layers;

FIG. 5 illustrates a three-dimensional, cross-section view of the nanotube, negative capacitance field effect transistor with ferroelectric layers;

FIGS. 6A to 6C illustrate various views of the nanotube, negative capacitance field effect transistor with ferroelectric layers;

FIGS. 7A-7F illustrate the various stages of forming the nanotube, negative capacitance, field effect transistor with ferroelectric layers; and

FIG. 8 is a flowchart of a method for forming the nanotube, negative capacitance, field effect transistor with ferroelectric layers.

### DETAILED DESCRIPTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a nanotube, negative-capacitance (NC), field effect transistor (FET) with ferroelectric layers. However, the embodiments discussed herein are not limited to this transistor, but may be applied to other transistors.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

Presently, the single gate-all-around (GAA) nanowire FET (NWFET) transistor is considered as the ultimate short channel device for future device technology due to its steep subthreshold slope (SS), low leakage power, and superior gate control. Recently, nanowire-NCFET (NW-NCFET) were found to have a higher Iₒₙ/I_{off} ratio than classical NW-MOSFET due to NC effect of a ferroelectric (FE) layer. Also, NW-NCFET were found to have two times higher Iₒₙ/I_{off} ratio than DG-NCFET due to GAA NW channel structure of NW-NCFET. The inventors have shown in previous work that a nanotube (NT) FET shows 10 times higher drive current, improved SS, and comparable I_{off} to that of a single NWFET. By using an array of NWFETs to achieve the same drive current as the NTFET, the NTFET structure is found to use 15% of the total area needed by the NWFET array.

Consequently, the inventors expect that a silicon NT-NCFET with ferroelectric layers would result in a higher Iₒₙ/I_{off} ratio than NW-NCFET and classical NTFET, in addition to achieving a higher area efficiency.

Before explaining the structure of the novel silicon NT-NCFET device with ferroelectric layers, a brief discussion about the existing high-end low-power transistors and their limitations is believed to be in order. The fundamental physics of a classical transistor operation has been the reason for not being able to further scale down the power supply. In a transistor, the carriers in the channel follow the Boltzmann distribution where a minimum of K_{B}T log 10=60 mV is needed to increase the drain current by a factor of ten. To achieve a fair Iₒₙ/I_{off} ratio (i.e., a ratio between the high performance and low power currents), a 1 V supply voltage is required. As a result, no matter the novelty of the transistor design, whether MOSFET, FDSOI-FET, FinFET or GAA NWFET, the sub-threshold shape SS cannot be reduced below 60 mV/dec due to fundamental physics limitations.

It is currently agreed that in order to get a steeper SS, transistors based on new operation mechanisms are needed. Salahuddin et al. (see, S. Salahuddin and S. Datta, Tech. Dig. Int. Electron Devices Meeting (2008) pp. 693-696) has first proposed the negative capacitance (NC) FETs to overcome the Boltzmann limitation in traditional transistors. The structure of the NCFET is basically the same as a FET, but a FE layer is introduced below the gate, so that the transistor exhibits a differential negative capacitance. The SS is expressed as

$$( \frac{\partial {V}_{G}}{\partial {ϕ}_{s}} ) ( \frac{\partial {ϕ}_{s}}{\partial {log}_{10} {I}_{D}} ) ,$$

where the second term is equal to 60 mV/dec. However, due to the negative capacitance in the FE layer, the first term of the SS formula, known as the m factor, will be smaller than 1, which means that an SS smaller than 60 mV/dec can be achieved.

Recently, a group of researchers have demonstrated a wafer-scale integration of NC-FinFETs at the 14-nm node having steeper SS and higher on current than control devices. They also showed NC-FinFETs based ring oscillators operating at 40 GHz and dissipating 40% less active power than control FETs which shows that NCFETs are promising for low-power and high-performance technology (see, Krivokapic, Z. et al. (2017), IEDM 2017).

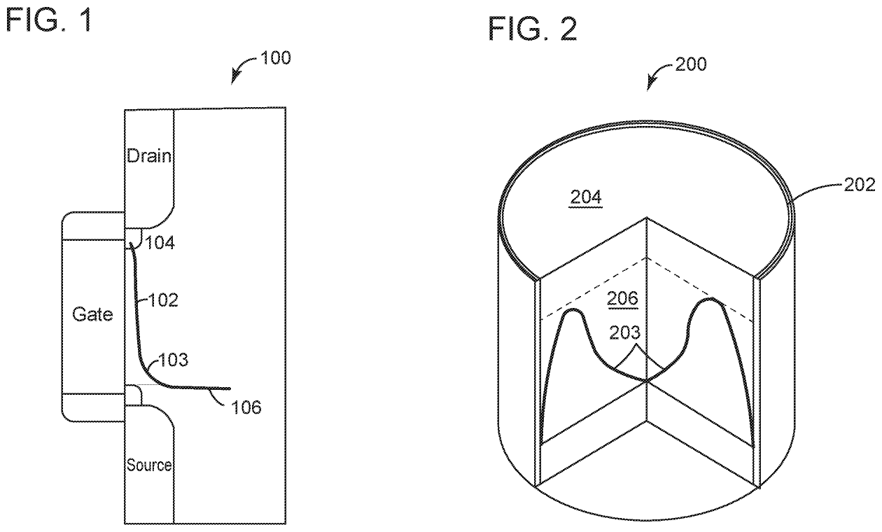

To understand why the GAA NWFET is such a popular architecture, a brief overview of the charge carrier control, distribution and movement in the channel is required from the perspective of the classical transistor. When a classical planar transistor 100, as shown in FIG. 1, is turned ‘on’, the charge carriers in the channel 102 are distributed in a parabolic Gaussian fashion 103 and they are localized near the oxide/silicon interface, with a maxima near the drain/channel interface 104 and tailing off with a minima into the bulk (Si substrate) 106. The carriers in the lower tail end of the profile 103 have low-energy and do not contribute significantly to the output drive current. In a silicon GAA NWFET, as illustrated in FIG. 2, the cylindrical body 200 is wrapped all around by the gate 202. Thus, when the gate is biased, several Gaussian profiles 203 are created in the channel 206 and around the circumference of the nanowire 204. As the thickness of the nanowire 204 is reduced, the carrier profile starts shifting away from the interface and into the volume of the device and there is more quantization of tail-end carrier energies until the profile approaches a parabolic distribution. At this point, the nanowire 204 is said to have achieved full volume inversion, where previously, interface-localized minority charge carriers are now volume (bulk)-localized. Benefits of this phenomenon are (i) increased carrier density leading to a higher I_{ON}, (ii) reduced off-state leakage current I_{off}, (iii) excellent electrostatic control leading to very low DIBL, (iv) low sub-threshold swing (SS), (v) reduced mobility degradation due to interface defects (present in planar transistors), and (vi) a uniform mobility distribution.

To summarize, the above phenomenon occurs only in very thin nanowires (NWdia<10 nm) and the overall benefit of this is the ultimate electrostatic control of charges in the channel leading to extremely low off-state current (I_{off}) and short channel effects (SCE). Although, due to the GAA architecture, the above phenomenon does lead to a higher current per μm from the nanowire, at the same time, the total cross-sectional area for the current flow is constricted by the same gate-all-around. As a result of this, the total non-normalized output drive current from a single GAA NWFET is extremely low for appreciable performance compared to classical planar transistors. In order to boost the output drive current, several nanowires have to be integrated into arrays. This increases the consumption of more chip area and counters the benefit of having small devices for more functionality per mm² of silicon. Studies have shown that this increased chip-area results to increased power consumption and chip delays.

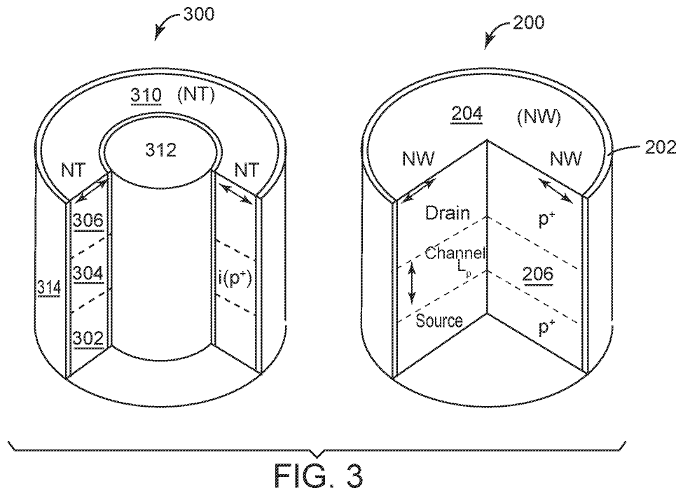

A nanotube FET transistor (NTFET) 300 is illustrated in FIG. 3 and uses a nanotube 310 instead of a nanowire 204 as in the previous embodiment, which is also illustrated in this figure for a direct comparation of the two structures. As discussed above, a ultra-narrow diameter (<10 nm) nanowire 204 offers extremely low-leakage characteristics and minimal short channel effects (SCE), owing to the superior electrostatic charge control from the gate 202 wrapping all around the nanowire channel 206. The excellent charge control is due to the volume localized charge transport as opposed to surface localized transport in classical planar transistors. The degree of control strongly depends on the nanowire diameter, with thinner nanowires offering more volume-inverted properties leading to higher normalized performance and lower leakage as well as SCE. However, as the nanowire diameter is reduced, the effective device width (W) is reduced and the total non-normalized drive current goes down. This is a problem that is also present in current-generation FinFET technology, which is being overcome by arraying more devices together to boost the effective device width. This approach comes at the expense of increased chip area, which may in-turn have a counter-productive impact on performance by introducing new sources of parasitic capacitances and resistances. The NWFET 300 has the source 302, channel 304, and drain 306 formed, as shown in FIG. 3, within the nanotube 310, between an inner core gate 312 and an outer shell gate 314.

According to an embodiment, a silicon NT-NCFET structure is introduced as a solution to achieve ultralow power consumption and highest Iₒₙ/I_{off} ratio. The inventors have shown that NT based FETs allow for improved electrostatics (lower subthreshold slope), high drive current, better immunity to short channel effects, and higher carrier mobility. Therefore, by introducing a ferroelectric (FE) layer below the gate of a NTFET baseline, and by achieving NC, the gate voltage will get amplified leading to an SS lower than 60 mV/dec. Because the NTFET provides excellent gate control bridging between high performance and low power regimes, it is expected that the novel NC-NTFET with FE layer will further lower the power consumption and improve the performance of the NTFET baseline, leading to the highest Iₒₙ/I_{off} and ultralow power consumption.

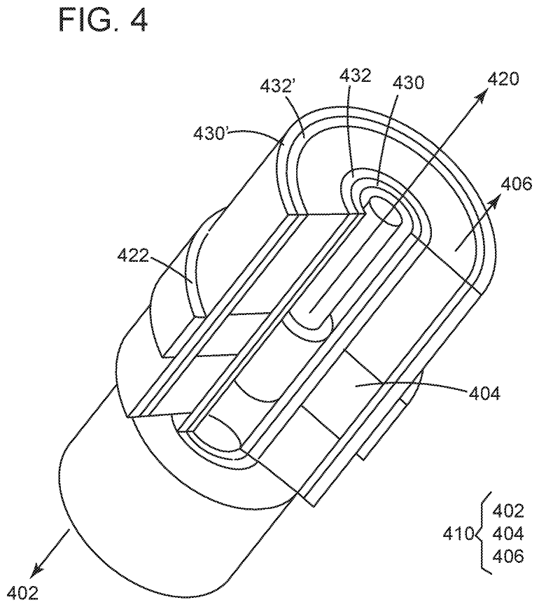

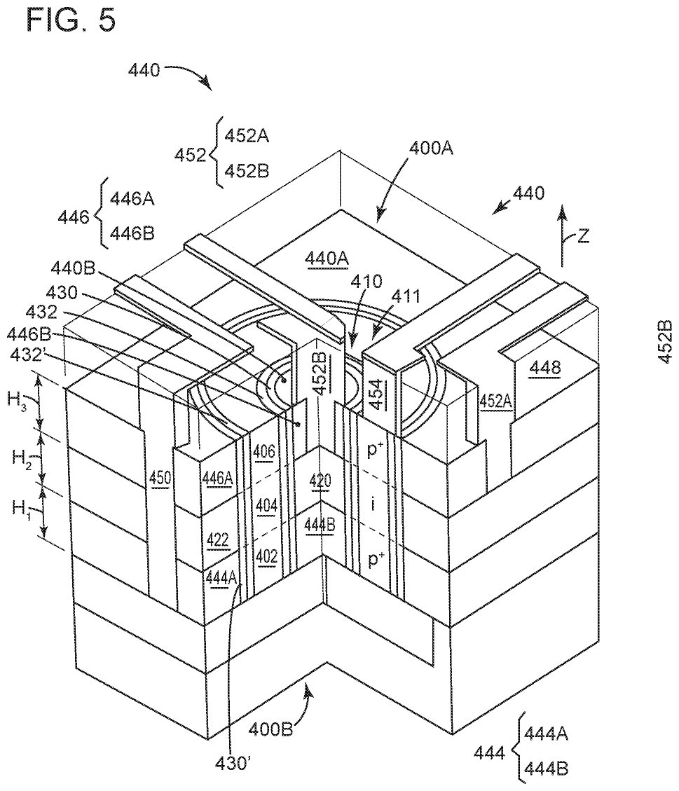

According to an embodiment, a NT-NCFET device 400 with FE layer is shown in FIG. 4 and includes a source region 402, a channel region 404, and a drain region 406 formed as a vertical structure. This vertical structure is better seen in FIG. 5 and it is defined as being vertical relative to the substrate of the device. Note that the source region 402, channel region 404, and the drain region 406 are formed (as discussed later) as a nanotube structure 410. The nanotube structure may be made by silicon with each region being appropriately doped, as discussed later. Inside the nanotube structure 410, there is formed a core gate 420. Outside the nanotube structure is formed a shell gate 422. The two gates 420 and 422 are used to control the number of carriers that pass through the channel region 404, from the source to the drain regions. Note that the sizes of the source, channel and drain regions are in the nanometers range.

Along the core gate 420 and outside of it, a first FE layer 430 is formed so that this layer separates the core gate 420 from the source, channel and drain regions. In other words, the first FE layer 430 extends along an internal circumference of the nanotube structure 410. A first gate dielectric layer 432 is formed along the first FE layer 430 as shown in FIG. 4. While FIG. 4 shows a cross-section of the basic parts of the NW-NCFET device 400, FIG. 5 shows a more complete configuration of the same device. The first gate dielectric layer 432 is in direct contact with the source, channel, and drain regions. The first gate dielectric layer 432 and the first FE layer 430 are substantially parallel to each other. Both of these two layers are formed inside a nanotube trench 411 (see FIG. 5) that holds the nanotube structure.

The shell gate 422 is separated from the channel region 404, and also from the source and drain regions 402 and 404, by a second FE layer 430′ and a second gate dielectric layer 432′. As shown in FIGS. 4 and 5, each of the dielectric layers 432 and 432′ is in direct contact with a corresponding FE layer 430 and 430′, respectively. In one application, the FE layers 430 or 430′ extend along the gate dielectric layers 432 and 432′, respectively, so that the FE layers completely cover the corresponding dielectric layers. In another application, a lateral surface area of the FE layers is smaller than a lateral surface area of the dielectric layers. The second FE layer 430′ extends along an external circumference of the nanotube structure 410. In one embodiment, the second gate dielectric layer 432′ is formed to extend on the external circumference of the nanotube structure 410, and the second FE layer 430′ extends along an external circumference of the second gate dielectric layer 432′.

Note that FIG. 4 shows that the core gate 420 extends inside the nanotube structure 410, only to face the channel region 404. This means that according to this embodiment, there is no core gate 420 inside the nanotube trench 411 (see FIG. 5), at regions corresponding to the source and drain regions. Also note that the structure shown in FIGS. 4 and 5 show a vertical structure, where the source, channel and drain regions are vertically arranged on top of each other and not in a horizontal direction, as in most traditional FET transistors.

FIG. 5 shows that the source region 402 is p doped, the drain region 406 is also p doped, and the channel region 404 is made of a semiconductor material. This figure also shows how the source, channel and drain regions are located in the nanotube structure 410, which is formed in the nanotube trench 411. The nanotube trench 411 is formed within a body 440. Body 440 of the NT-NCFET device 400 includes various other elements, which are now discussed. For example, body 440 is formed on a Si or Ge substrate 442. Vertically on the Si substrate 442, the nanotube structure 410 is built, as discussed later. The body 440 includes a spacer layer 444, which extends around the source region 402, substantially having the same height H1 along a vertical axis Z, as the source region 402. In one application, the heights of the spacer layer and the source region are different. Note that the spacer layer 444 occupies the space around the nanotube structure 410, i.e., external to the nanotube structure, but also inside the nanotube structure 410. In other words, the spacer layer has an outside part 444A and an inside part 444B, and the two parts are mechanically separated from each other by the nanotube structure 410. The spacer layer 444 may be, in one embodiment, in direct contact with the second FE layer 430′, outside the nanotube structure, and also in direct contact with the first FE layer 430, inside the nanotube structure.

In top of the spacer layer 444, as illustrated in FIG. 5, there is the shell gate 422, extending outside the nanotube structure 410. The shell gate 422 may have a second height H2. Inside the nanotube structure 410, there is the core gate 420, which is formed on top of the inside part 444B of the spacer layer 444, and also inside the nanotube structure 410. The core gate 420 may have the same or a different height from the second height H2. The second height H2 is also the height of the channel region 404.

Another spacer layer 446 (second spacer layer) is formed on top of the shell gate 422 and the core gate 420, thus having an external part 446A formed (e.g., directly) on top of the shell gate 422 and an internal part 446B formed (e.g., directly) on top of the core gate 420. A height of the spacer layer 446 may be H3, which may be the same or not for the internal and external parts of this layer. This second spacer layer 446 may have a same height as the drain region 406 and thus, it sandwiches the drain region 406. Finally, on top of the second spacer layer 446, there may be a protection layer 448 (for example, an inter layer dielectric (ILD), which constitutes the top side 400A of the device 400. Note that the Si substrate 442 constitutes the bottom side 400B of the device 400. The body 440 includes at least the first spacer layer 444, the shell and core gates 420 and 422, and the second spacer layer 446. In one application, the body 420 may also include the protection layer 448.

The electrical contacts from the various components of the device 400 to the top side 400A of the device are now discussed. As shown in FIG. 5, there is a source contact 450, which extends vertically along the axis Z, from the Si substrate all the way to the top side 400A of the device. A gate contact 452, which also extends along the vertical direction Z, is provided between the gate and the top side 400A of the device 400. Gate contact 452 includes an external gate contact 452A that directly connects to the shell gate 422 and an internal gate contact 452B that directly connects to the core gate 420. The two gate contacts 452A and 452B may be electrically connected to each other or not for controlling the two gates 420 and 422.

A drain contact 454 extends also vertically, from the drain region 406, inside the nanotube, to the top side 400A of the device. Note that the source contact 450 and the external gate contact 452A extend substantially parallel to a longitudinal axis of the nanotube configuration 410 and also outside the nanotube configuration, the internal gate contact 452B extends substantially parallel to the longitudinal axis Z and inside the nanotube structure 410, and the drain contact 454 extends substantially parallel to the longitudinal axis Z and within the nanotube structure 410.

FIG. 5 also shows that the body 440 has a first part 440A formed outside the nanotube trench 411 and a second part 440B formed inside the nanotube trench 411. In this regard, the term “inside” is used in this application to mean that something is formed in the space encircled by the nanotube structure 410. When the term “within” is used with regard to the term “nanotube structure,” it means the internal space of the nanotube structure, i.e., the space where the source, channel and drain regions are formed.

The device shown in FIGS. 4 and 5 can be described as a nanotube, negative capacitance, field effect transistor with ferromagnetic layers. In summary, this transistor includes a substrate 442, a body 440 including plural layers 444, 420, 422, 446, the body 440 being formed on top of the substrate 442, a nanotube trench 411 formed vertically into the body 440 and extending to the substrate 442, a source region 402, a channel region 404, and a drain region 406 formed vertically on top of each other within the nanotube trench 411. The source region 402, the channel region 404 and the drain region 406 are encircled along an internal circumference by a first gate dielectric layer 432 and by a first ferroelectric layer 430, in this order, and also are encircled along an external circumference by a second gate dielectric layer 432′ and by a second ferroelectric layer 430′, in this order.

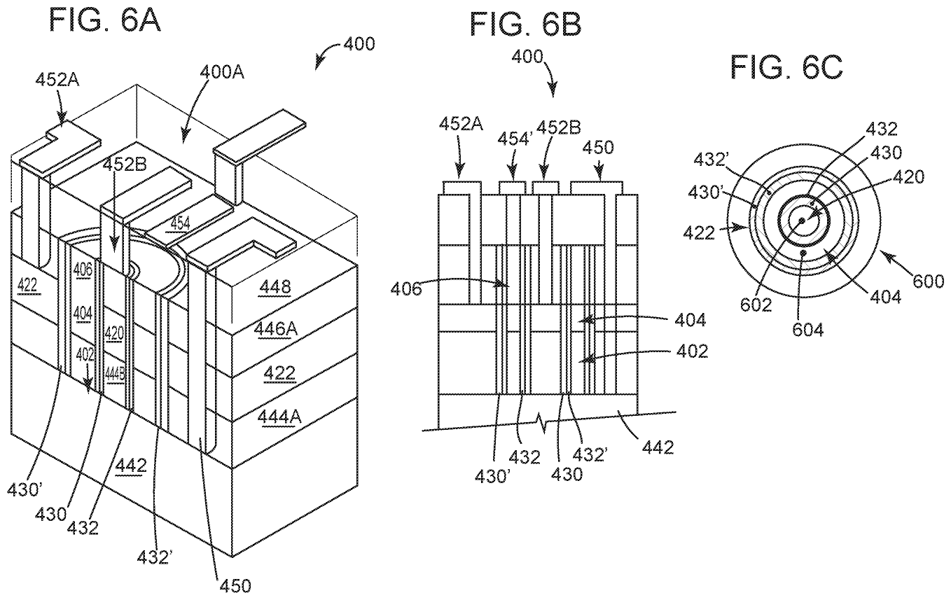

FIGS. 6A to 6C show a 3D cross-section, 2D vertical cross-section, and 2D horizontal cross-section, respectively, of the device 400 for a further exemplification of the various layers and contacts that are part of the device. It is noted that the FE layers 430 and 430′, which are internal and external to the nanotube structure 410, respectively, extend vertically all the way from the Si substrate 442 to the top side 400A of the device 400. FIG. 6C is a cross-section of the nanotube structure 410 made at a height corresponding to the channel region 404. FIG. 6C also shows a region 600 external to the nanotube structure 410, a region 602 internal to the nanotube structure 410, and a region 604 within to the nanotube structure 410. Note that while the previous figures show the FE layers 430 (430′) formed below the gate layers 432 (432′), those skilled in the art would know to experiment the placement of the FE layers at other locations, for example, above the gate layers.

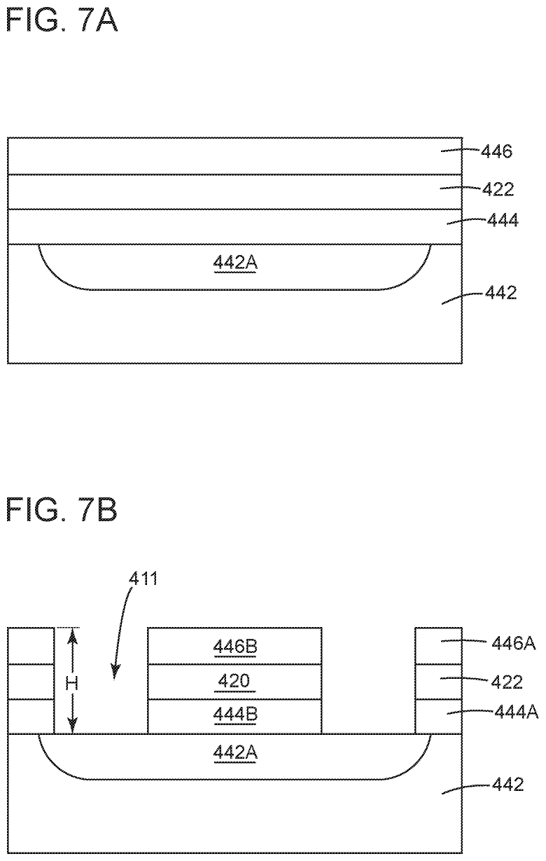

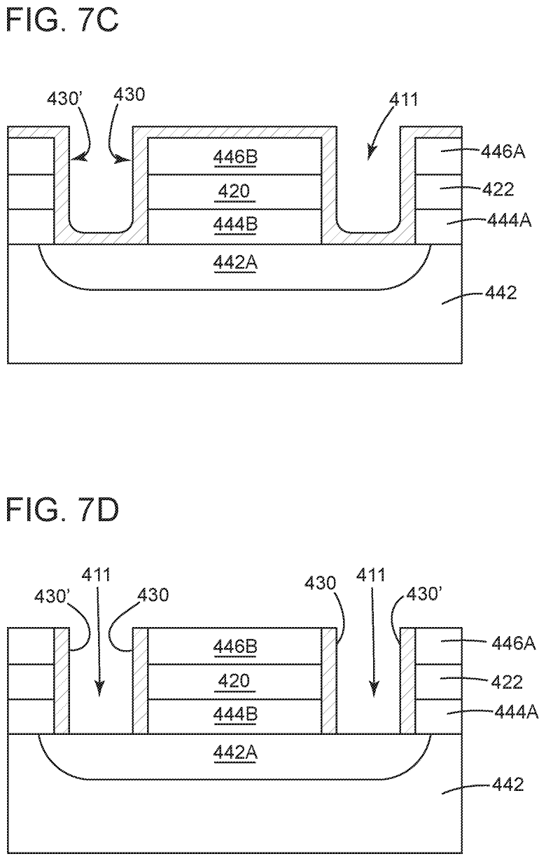

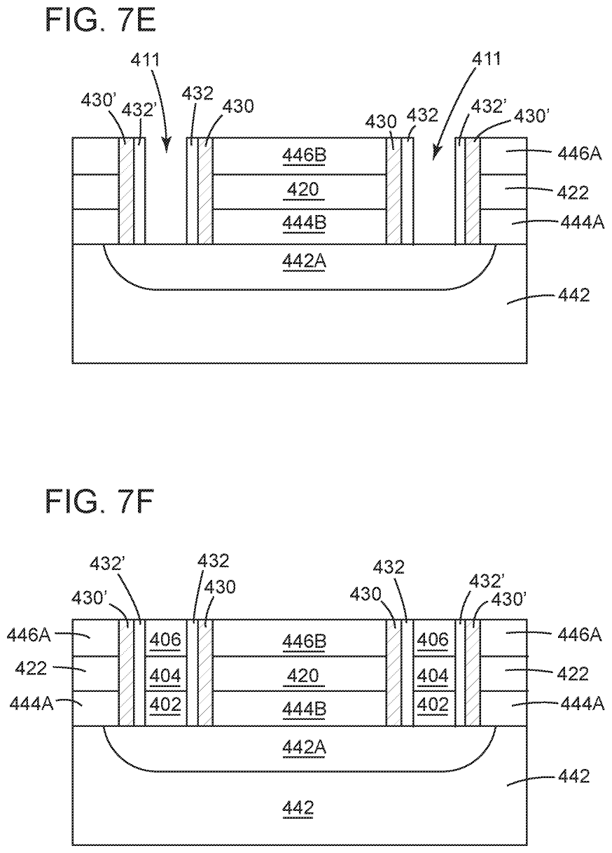

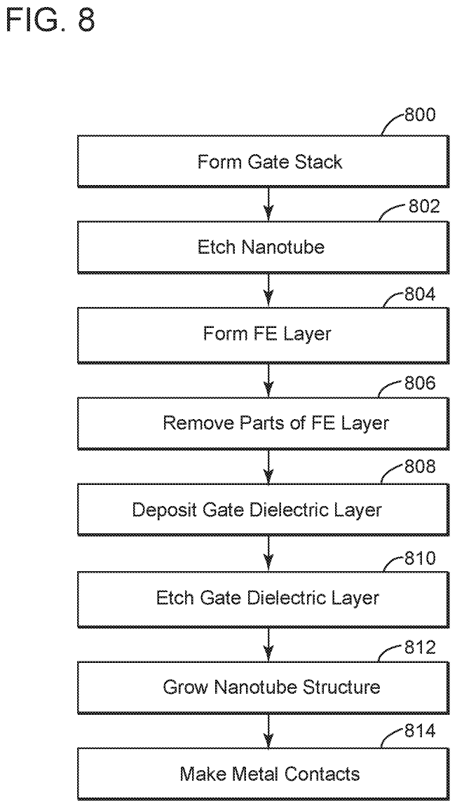

A method for forming the NT-NCFET device 400 with FE layers illustrated in FIGS. 4 to 6C is now discussed with regard to FIGS. 7A to 8. Note that the process discussed herein (see flowchart of FIG. 8) is a highly compatible CMOS process that offers several key potential advantages:

(i) The device channel length (Lg) is defined by the thickness of the deposited material enabling the formation of ultra-short channel devices. Such a process is immune to bottlenecks due to lithographic constraints and the shortest gate length is defined by the minimum thickness of the deposited material. Atomic layer deposited gate materials can be theoretically used to achieve sub-nm gate length devices.

(ii) The nanotube thickness can be controlled by the deposited gate dielectric thickness allowing ultra-narrow width nanotube FETs. Initial nanotube trenches can be defined using conventional lithography. Using high-K gate dielectric enables the use of thick materials while maintaining a low effective oxide thickness.

(iii) Epitaxial growth of the nanotube structure allows the formation of highly abrupt source/channel and drain/channel junctions. This requires a low temperature epitaxial growth process to reduce unwanted dopant diffusion across the junctions.

In a classical MOSFET, the gate stack usually includes a planar conductive metal (traditionally heavily doped polycrystalline silicon) layer formed on top of an insulating dielectric (traditionally SiO₂), which in turn is formed on top of the silicon substrate. Vertical spacers (Si₃N₄) on either side isolate the gate contact from the source and drain contacts. In the vertical NT-NCFET device 400, this gate stack may be rotated exactly 90° counter clockwise and consists of a heavily doped poly-silicon gate 422 sandwiched between two low-K SiO₂ spacer layers 444 and 446, as illustrated in FIG. 7A. A substrate 442 is provided and the gate stack is formed on the substrate 442 in step 800. In one application, the first spacer 444 may have a thickness of 45 nm, the gate 422 may be made of poly-silicon having a thickness of about 25 nm, and the second spacer 446 may have a thickness of about 20 nm, where the poly-silicon gate 422 has n++ heavy doping achieved thermally using phosphorus-oxyl-chloride (POCL₃). This doping technique produces a nearly uniform doping profile. Note that a heavily doped well 442A may also be formed in the Si substrate 442. Those skilled in the art would know that other materials may be used for the substrate, for example, Ge.

Next, a nanotube trench 411 was etched into the above discussed body. This is a sensitive step in the process flow as it defines the minimum possible nanotube thickness that can be achieved. For example, using a 100 keV electron beam lithography and a diluted (1:1) positive resist (ZEP520A: Anisole), a minimum feature size of 50 nm was achieved in step 802. This step achieves a highly vertical trench 411 (see FIG. 7B) etched in the oxide/poly-silicon/oxide gate structure illustrated in FIG. 7A and also minimizes surface damage on the silicon seed substrate 442. Note that at this step, the gate layer 422 is actually split into the core gate 420 and the shell gate 422. Also, the first spacer layer 444 is split into the outside part 444A and the inside part 444B and the second spacer layer 446 is split into the outside part 446A and the inside part 446B. As discussed above, the first and second spacer layers may be made of SiO₂.

To obtain these features, a reactive ion etcher (RIE) was used. Highly directional transport of reactive ion gases (Cl₂/HBr for Si; CF₄/CHF₃ for oxides and nitrides) combined with a noble carrier gas plasma (Ar) were used for obtaining the vertical nanotube trench 411. This process step takes advantage of the vertical nitride based spacer isolation in classical planar MOSFETs, where traditionally, they have been used to isolate the gate from the source and drain regions. FIG. 7B shows the nanotube trench 411 after it has been etched all the way to the silicon substrate 442 and the nanotube channel has a thickness T of about 50 nm. The thickness T may be smaller. A depth H of the nanotube trench 411 may be 100 nm or less.

In step 804, an FE layer 430/430′ (for example, hafnium and zirconium based oxides deposited by atomic layer deposition or PZT deposited by sol-gel spin coating or transfer printing (with seed layer if any is required) is formed inside the nanotube trench 411 to cover the sides of the shell gate 422, the core gate 420, and the inside and outside parts 444A, 444B, 446A, and 446B of the first and second gate dielectric layers, as illustrated in FIG. 7C. Then, in step 806, inductively coupled Plasma Reactive ion etching tool is used to remove the bottom portions of the FE layer, and the parts of the FE layer that are formed directly on the substrate 442 and on top of the second spacer layer 446A/446B, as illustrated in FIG. 7D, so that the first and second FE layers 430 and 430′ are present only inside the nanotube trench 411. At this point, the first FE layer 430 is separated from the second FE layer 430′ as illustrated in the figure.

In step 808, a conformal deposition of an insulating and highly dense nitride (spacer) layer 432/432′ by a high temperature may be achieved by low pressure chemical vapor deposition (LPCVD). This subtractive technique utilizes the thickness of the nitride spacer layer (in this case 20 nm) to narrow the trench width to approximately 10 nm, as depicted in FIG. 7E. Taking advantage of the highly conformal nature of the gate dielectric material 432/432′, a highly anisotropic Si₃N₄ etch, that is selective to SiO₂, is used in step 810 to etch away the lateral portion of the spacer layer, while the vertical sidewall portions remain attached to the FE layers.

Next, the nanotube structure 410 needs to be formed in the nanotube trench 411. In one embodiment, it is possible to use silicon selective epitaxial growth (SEG) to form the source, channel and drain regions of the nanotube structure in step 812. Epitaxy is the process of growing crystalline semiconducting materials from a seed substrate. Although, there are several types of this process, homo and hetero epitaxy are the two dominant processes for growing group-IV and III-V semiconductors. Homoepitaxy deals with material growth with similar crystal structure as the seed substrate (silicon, germanium) while heteroepitaxy is used for growing dissimilar materials (such as InAs, InGaAs). Of the two processes, silicon epitaxy has been in wide use for CMOS. In the past, as classical planar transistors where scaled down, the implanted source and drain junctions became very shallow and this led to the term ‘ultra-shallow-junctions’. Such shallow junctions increase the contact access resistance leading to poor drive current performance. To overcome this, selective silicon epitaxy was utilized to ‘raise’ the source/drain regions. This CMOS technique has been adapted here to form the nanotube source, channel and drain regions. Epitaxy is a very sensitive bottom-up growth process that is highly susceptible to minute changes in process conditions.

The step of silicon epitaxy 812 in this embodiment has been achieved in a cold-wall rapid thermal chemical vapor deposition chamber (RTCVD) with SiH₂Cl₂ (Dichlorosilane—DCS) and H₂ as the source gas. For n-type doping, diluted PH₃ (100 ppm in He) was utilized as the source gas. P-type epitaxial doping may also be used.

The step of epitaxial growth was implemented in two sub-steps. The first sub-step involved a low-temperature growth of a buffer silicon layer (around 600° C.) to heal any RIE-induced surface damage from the substrate 442. At such low temperature, the deposition rate is around 0.5 nm/min. After about 5 nm of silicon buffer layer growth, the second sub-step follows as the temperature is ramped up to 700° C. and the growth proceeds at a rate of 1 nm/min. In both sub-steps, the deposition pressure is about 150 mTorr, with DCS flow rate of 30 sccm and hydrogen flow rate of 180 sccm. Doping in the source region 402 and the drain region 406 (see FIG. 7F) is achieved by a dopant source gas flow rate in between 112.5 sccm-142.5 sccm of PH₃. In non-epitaxial growth, single crystal silicon is formed on the silicon substrate 442 while polycrystalline silicon nucleates on dielectrics such as SiO₂ and Si₃N₄. Silicon nucleation and further deposition on SiO₂ is comparatively much slower than on silicon. Using SiH₂Cl₂+H₂ source gas chemistry provides an inherent HCl content that takes advantage of the delayed nucleation times to effectively remove any silicon growth on oxide based dielectrics, leading to complete selective epitaxy in oxide patterned trenches.

Traditionally, ion implantation, which involved accelerated bombardment of dopant species such as As, P, B etc., has been used to heavily dope the source and drain regions. In the planar transistor topology, achieving retrograde steep doping profiles became more challenging, especially when dealing with ultra-shallow junctions. Furthermore, once the dopants have been implanted, a very high thermal budget drive-in anneal (flash anneal, laser anneal, spike anneal) is required to ‘activate’ or move them to their appropriate low energy substitutional lattice sites. Additionally, ion-implantation is a damage-inducing process that amorphizes the single crystal silicon. Because of this, the CMOS industry now uses pre-amorphization molecular carbon implants to deliberately damage the surface before ion-implantation as a damage-control measure.

In-situ epitaxial doping has been explored in the past to achieve very steep junctions. This process offers several potential advantages over conventionally used ion-implantation. Firstly, doped epitaxial growth occurs only when there is dopant source gas flow. It becomes very easy to create very steep and precisely aligned doping junctions leading to minimized parasitic capacitances and resistances due to underlap/overlap. Secondly, in-situ doping places dopants in their appropriate substitutional sites in the silicon crystal lattice without the need for activation anneal. As discussed earlier, diluted PH₃ (100 ppm in He) is used as the dopant source gas for in-situ doping of the source and drain regions.

In one application, one doping profile with the largest separation between source/drain regions and channel region doping levels may be obtained with a PH₃ flow rate of 142.3 sccm and epitaxial growth temperatures of 720° C. in the source and drain regions 402 and 406 and 680° C. in the “intrinsic—i” channel region 404 with a maximum doping concentration of about 2×10²⁰ cm⁻³ and a minimum doping concentration of 4×10¹⁹ cm⁻³ respectively. Higher PH₃ flow rates were used to achieve larger separation, but due to process boundaries, the maximum achievable was about 5 times.

After the nanotube structure 410 is built as discussed above, the metal contacts shown in FIG. 5 are made in step 814 using known methods in the art. At this point, the manufacturing process of the NT-NCFET device 400 with FE layers is completed.

The details provided above with regard to the method of FIG. 8 are for illustrative purposes. Those skilled in the art would understand that the materials and various conditions (e.g., pressure, temperature, etc.) may be changed to still obtain the device 400. For example, the nanotube trench may be patterned using an ebeam lithography tool, and the source/channel/drain regions may be grown by selective epitaxy. Hafnium based oxides may be used as the FE material (such as FE HfO₂ or HfZrO) since they are CMOS compatible and more scalable than other FE materials such as PZT and BTO, where several hundreds of nanometers are needed to balance the FET channel charge density and the large polarization charge density in the FE layer.

The disclosed embodiments provide methods and electronic structures (e.g., transistors) that have a very-low power usage and are appropriate for the IoT devices. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. An electronic device comprising:
a substrate;
a body including plural layers, the body being formed on top of the substrate;
a nanotube trench formed vertically in the body and extending to the substrate; and
a nanotube structure formed in the nanotube trench,
wherein the nanotube structure is mechanically separated from the body by a gate dielectric layer and a ferroelectric layer.

2. The device of claim 1, wherein the nanotube structure comprises:
a source region formed on the substrate;
a channel region formed on the source region; and
a drain region formed on the channel region.

3. The device of claim 2, wherein the channel region is sandwiched between a shell gate and a core gate.

4. The device of claim 3, wherein the shell gate is formed outside the nanotube structure and outside the nanotube trench.

5. The device of claim 4, wherein the core gate is formed inside the nanotube structure and is encircled by the nanotube trench.

6. The device of claim 1, wherein the plural layers of the body includes:
a first spacer layer formed on top of the substrate;
a shell gate layer formed directly on top of the first spacer and outside the nanotube trench;
a core gate layer formed directly on top of the first spacer and inside the nanotube trench; and
a second spacer layer formed directly on top of the shell gate and the core gate.

7. The device of claim 1, wherein the ferroelectric layer is vertically formed along the nanotube structure.

8. The device of claim 7, wherein the ferroelectric layer is formed directly on the body.

9. The device of claim 7, wherein the ferroelectric layer is sandwiched between the body and nanotube structure.

10. The device of claim 1, wherein the body has a first part formed outside the nanotube trench and a second part formed inside the nanotube trench and the ferroelectric layer is formed on both an inside face and an outside face of the nanotube structure.

11. The device of claim 1, wherein the gate dielectric layer is vertically formed along the nanotube structure and in direct contact with the nanotube structure.

12. The device of claim 11, wherein the gate dielectric layer is formed on both an inside face and an outside face of the nanotube structure.

13. A nanotube, negative capacitance, field effect transistor with ferromagnetic layers, the transistor comprising:
a substrate;
a body including plural layers, the body being formed on top of the substrate;
a nanotube trench formed vertically into the body and extending to the substrate; and
a source region, a channel region and a drain region formed vertically on top of each other within the nanotube trench,
wherein the source region the channel region and the drain region are encircled along an internal circumference by a first gate dielectric layer and by a first ferroelectric layer, in this order, and also are encircled, along an external circumference, by a second gate dielectric layer and by a second ferroelectric layer.

14. The transistor of claim 13, wherein the first and second ferroelectric layers are vertically formed along the source region, the channel region, and the drain region.

15. The transistor of claim 14, wherein the first ferroelectric layer is sandwiched between the body and the first gate dielectric layer.

16. The transistor of claim 15, wherein the second ferroelectric layer is sandwiched between the body and the second gate dielectric layer.

17. The transistor of claim 13, wherein the body has a first part formed outside the nanotube trench and a second part formed inside the nanotube trench.

18. A method for forming an electronic device, the method comprising:
providing a substrate;
forming a body, including plural layers, on the substrate;
etching a nanotube trench vertically into the body;
forming a ferroelectric layer on the sides of the nanotube trench;
depositing a gate dielectric layer on the ferroelectric layer; and
growing a nanotube structure in the nanotube trench,
wherein the nanotube structure is separated from the body by the gate dielectric layer and the ferroelectric layer and the nanotube structure includes a source region, a channel region and a drain region.

19. The method of claim 18, wherein the ferroelectric layer is in direct contact with the body and the gate dielectric layer.

20. The method of claim 19, wherein the gate dielectric layer extends vertically along the source region, the channel region and the drain region of the nanotube structure.
